(19) United States
(12) Patent Application Publication
(10) Pub. No.: US 2026/0163357 A1
(43) Pub. Date: Jun. 11, 2026

(54) PROTECTION DRIVE CIRCUIT FOR A BATTERY SYSTEM

(71) Applicant: ZGMICRO HEFEI CO., LTD., Hefei (CN)

(72) Inventor: Hang YIN, Hefei (CN)

(21) Appl. No.: 19/395,249

(22) Filed: Nov. 20, 2025

(30) Foreign Application Priority Data
Nov. 27, 2024 (CN) 202411721775.8

(51) Int. Cl. H02H 7/18; H03K 17/687

(52) U.S. Cl. CPC H02H 7/18; H03K 17/687

(57) ABSTRACT

A protection drive circuit for a battery system includes: a first drive transistor and a second resistor coupled in series between a positive electrode of a battery and a drive output terminal; a second drive transistor coupled in series between the drive output terminal and a negative output terminal; a first resistor coupled in series between a gate of the second drive transistor and a control input terminal coupled to a gate of the first drive transistor and configured to receive a control signal; and a clamp circuit coupled between the gate of the second drive transistor and the negative output terminal. The clamp circuit is configured to clamp a voltage difference between the gate of the second drive transistor and the negative output terminal within a predetermined voltage. This circuit allows the drive transistors to be low-voltage transistors, reducing manufacturing cost.

### CROSS-REFERENCE OF RELATED APPLICATIONS

The present invention claims priority of Chinese Patent Application No. 202411721775. 8 filed in China on Nov. 27, 2024, the entire contents of which are incorporated herein by reference.

### BACKGROUND OF THE INVENTION

### Field of the Invention

The present invention relates to the technical field of battery protection chip design, and specifically relates to a protection drive circuit for a battery system.

### Description of the Related Art

Battery protection chips, particularly those for low-voltage batteries with an output voltage below 5V, require a drive transistor responsible for a gate control signal of a charge control transistor on a protection board to withstand high voltages up to 20V or even 28V. Therefore, high-voltage-resistant transistors must be selected as the drive transistors for the gate control signal in the circuit design. However, high-voltage-resistant transistors rely on high-cost, high-voltage manufacturing processes for their realization, which results in relatively high manufacturing costs for battery protection chips.

### SUMMARY OF THE INVENTION

One objective of the present invention is to provide a protection drive circuit for a battery system, so as to solve the technical problem of high manufacturing costs of battery protection chips designed in related technologies.

In a first aspect, a protection drive circuit for a battery system is provided according to one embodiment of the present invention. The protection drive circuit comprises: a first drive transistor and a second resistor coupled in series between a positive electrode of a battery and a drive output terminal, wherein a gate of the first drive transistor is coupled to a control input terminal configured to receive a control signal; a second drive transistor coupled in series between the drive output terminal and a negative output terminal; a first resistor coupled in series between a gate of the second drive transistor and the control input terminal; and a clamp circuit coupled between the gate of the second drive transistor and the negative output terminal, wherein the clamp circuit is configured to clamp a voltage difference between the gate of the second drive transistor and the negative output terminal within a predetermined voltage.

In the present disclosure, the arrangement of the second resistor provides voltage division and current limiting for the first drive transistor, while the arrangement of the first resistor provides voltage division and current limiting for the second drive transistor. This ensures that normal operating voltages of both the first and second drive transistors remain within a low-voltage range, thereby enabling the use of low-cost low-voltage transistors for the first drive transistor and the second drive transistor to reduce the overall manufacturing cost of the protection drive circuit. Among these components, the clamp circuit is provided to prevent irreversible damage caused by direct breakdown of the gate of the second drive transistor under extreme operating conditions, thereby extending a service life of the second drive transistor and reducing post-maintenance cost of the protection drive circuit.

There are many other objects, together with the foregoing attained in the exercise of the invention in the following description and resulting in the embodiment illustrated in the accompanying drawings.

### BRIEF DESCRIPTION OF THE DRAWINGS

These and other features, aspects, and advantages of the present invention will become better understood with regard to the following description, appended claims, and accompanying drawings wherein:

FIG. 1 is a schematic diagram of a protection drive circuit for a battery system according to one embodiment of the present invention;

FIG. 2 is a schematic diagram of a battery protection circuit and its external circuit according to one embodiment of the present invention; and

FIG. 3 is a schematic diagram of five implementation modes of a clamp circuit according to one embodiment of the present invention.

### DETAILED DESCRIPTION OF THE PREFERRED EMBODIMENTS

The detailed description of the invention is presented largely in terms of procedures, operations, logic blocks, processing, and other symbolic representations that directly or indirectly resemble the operations of data processing devices that may or may not be coupled to networks. These process descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be comprised in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams representing one or more embodiments of the invention do not inherently indicate any particular order nor imply any limitations in the invention.

In related technologies, for a protection chip of a low-voltage battery with an output voltage of 5V or below, a drive transistor for a gate control signal of a charging control transistor on its protection board is coupled between a protected battery and a negative output terminal. In application, since a voltage level of the negative output terminal may be as low as −20V or lower, a voltage difference between the battery and the negative output terminal may be as high as 20V or even 28V. Therefore, it is necessary to use high-voltage-resistant MOS transistors as the aforementioned drive transistors to avoid irreversible breakdown of the drive transistors, which would cause damage to the protection chip. However, high-voltage-resistant MOS transistors rely on high-voltage processes for manufacturing. These high-voltage processes are significantly more costly compared to standard low-voltage processes, the manufacturing cost of the drive transistors for the gate control signal of the charge control transistor becomes substantial. This, in turn, leads to an overall high manufacturing cost for the battery protection chip itself.

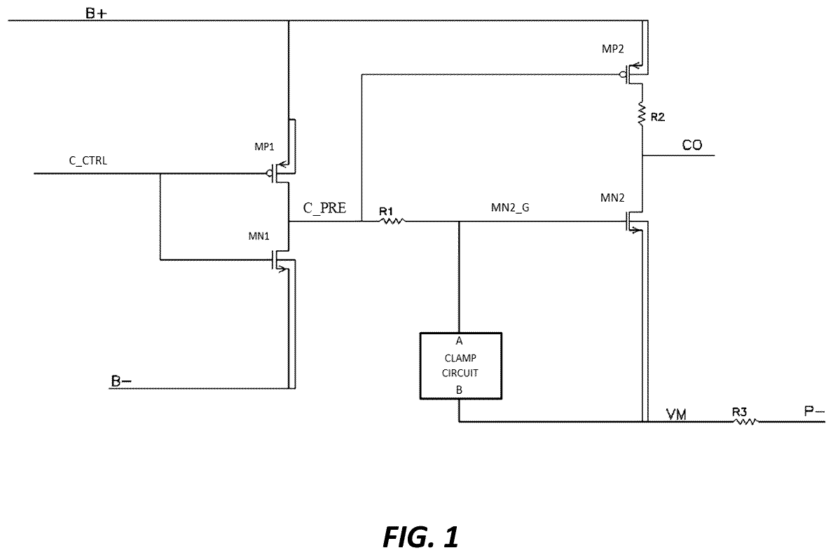

To solve the above problem, the present application provides a protection drive circuit for a battery system. As shown in FIG. 1, the protection drive circuit includes: a first drive transistor MP2 (a PMOS transistor) and a second resistor R2 coupled in series between a positive electrode B+ of the battery and a drive output terminal CO; a second drive transistor MN2 (an NMOS transistor) coupled in series between the drive output terminal CO and a negative output terminal P−; a first resistor R1 coupled in series between a gate of the second drive transistor MN2 and a control input terminal C_PRE; and a clamp circuit (CLAMP CIRCUIT) coupled between the gate of the second drive transistor MN2 and the negative output terminal P−.

A gate of the first drive transistor MP2 is coupled to the control input terminal C_PRE, and the control input terminal C_PRE is configured to receive a control signal. The clamp circuit is configured to clamp a voltage difference between the gate of the second drive transistor MN2 and the negative output terminal P− within a predetermined voltage.

A working principle of the protection drive circuit is as follows: the first drive transistor MP2 or the second drive transistor MN2 is turned on based on the control signal, so as to control the drive output terminal CO to output a drive signal with a corresponding high level or low level.

Specifically, the high level of the control signal is a voltage of the positive electrode B+ of the battery, and the low level of the control signal is a voltage of the negative electrode B− of the battery.

When the control signal is at the low level, the first drive transistor MP2 is turned on, the second drive transistor MN2 is turned off, the drive signal output by the drive output terminal CO is at a high level, and the high level of the drive signal is the voltage of the positive electrode B+ of the battery.

When the control signal is at the high level, the first drive transistor MP2 is turned off, the second drive transistor MN2 is turned on, the drive signal output by the drive output terminal CO is at a low level, and the low level of the drive signal is the voltage of the negative output terminal P−.

When a source and a drain of the first drive transistor MP2 are broken down by high voltage, the second resistor R2 can be used to realize current limiting and voltage division for the first drive transistor MP2, so as to prevent the first drive transistor MP2 from being burned by excessive current or voltage when it is turned on.

Similarly, when the clamp circuit (CLAMP CIRCUIT) is broken down, the first resistor R1 can be used to realize current limiting and voltage division for the second drive transistor MN2, so as to prevent the second drive transistor MN2 from being burned by excessive current or voltage when it is turned on.

That is to say, in the present application, by means of the arrangement of the first resistor R1 and the second resistor R2, normal operating voltages of the first drive transistor MP2 and the second drive transistor MN2 are maintained within a low-voltage range. This further enables the use of low-cost low-voltage transistors (compared to using MOS transistors with a voltage rating above 12V) as the first drive transistor MP2 and the second drive transistor MN2 in the protection drive circuit. On the premise of ensuring the normal realization of the function of the protection drive circuit, this reduces the manufacturing cost of the drive transistor for the gate control signal of the charging control transistor, and further reduces the overall manufacturing cost of the protection drive circuit.

Herein, the low-cost low-voltage transistors can be understood as a MOS transistor with a lower voltage rating compared to MOS transistors rated for voltages above 12V. In one example, the voltage rating capability of a MOS transistor can be reflected by a thickness of a gate oxide layer of the transistor. In this case, the low-cost low-voltage transistors may be transistors whose gate oxide layer thickness is smaller than that of MOS transistors with a voltage rating above 12V.

Among these components, the clamp circuit (CLAMP CIRCUIT) is arranged to clamp the voltage difference between the gate of the second drive transistor MN2 and the negative output terminal P-within the predetermined voltage. This can prevent irreversible damage caused by direct breakdown of a gate oxide of the second drive transistor MN2 under extreme operating conditions, thereby meeting requirement of using the low-voltage transistor as the second drive transistor MN2 and reducing the overall manufacturing cost of the drive circuit.

It can be understood that the predetermined voltage is lower than a gate oxide breakdown voltage of the second drive transistor MN2, where the gate oxide breakdown voltage specifically refers to a breakdown voltage of the gate oxide layer.

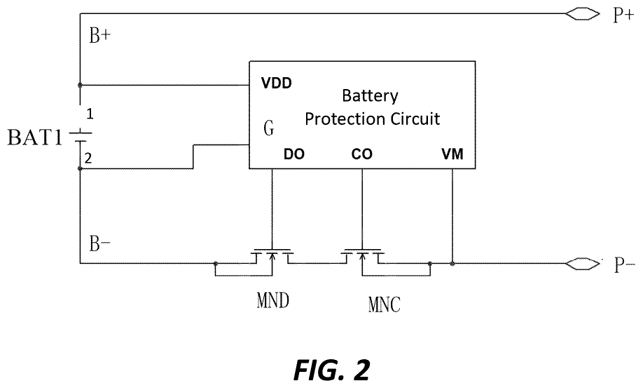

In one embodiment, a battery protection circuit corresponding to the protection drive circuit of the present invention and its external circuit may be as shown in FIG. 2. The battery protection circuit comprises a charging protection circuit and a discharging protection circuit, wherein the charging protection circuit comprises the aforementioned protection drive circuit. A charging control terminal CO (i.e., the aforementioned drive output terminal CO) of the charging protection circuit is coupled to a control terminal of a charging power switch MNC, and a discharging control terminal DO of the discharging protection circuit is coupled to a control terminal of a discharging power switch MND.

Specifically, the aforementioned drive signal is a charging drive signal, and a source and a substrate of the charging power switch MNC are coupled to the negative output terminal P−.

When the charging drive signal is at the high level, the charging power switch MNC is turned on, and the protected battery BAT1 is allowed to be charged. On the contrary, when the charging drive signal is at the low level, the charging power switch MNC is turned off, and the protected battery BAT1 is prohibited from being charged.

Similarly, when the discharging control terminal DO outputs a discharging drive signal at a high level, the discharging power switch MND is turned on, and the protected battery BAT1 is allowed to discharge. On the contrary, when the discharging drive signal is at a low level, the discharging power switch MND is turned off, and the protected battery BAT1 is prohibited from discharging.

The charging control signal C_PRE is generated by the protection drive circuit according to a charging status of the protected battery. When the battery does not need to be charged (e.g., in case of overcharging voltage or overcharging current), the charging control signal C_PRE is at the high level, the charging control terminal CO will output the charging drive signal at a low level to prohibit the battery from being charged. When the battery is allowed to be charged, the charging control signal C_PRE is at the low level, so that the charging control terminal CO outputs the charging drive signal at the high level to allow the battery to be charged.

Exemplarily, both the charging power switch MNC and the discharging power switch MND may be NMOS transistors.

In one embodiment, when the voltage difference between the gate of the second drive transistor MN2 and the negative output terminal P-is greater than or equal to the predetermined voltage, the clamp circuit (CLAMP CIRCUIT) is reversibly broken down to clamp the voltage difference between the gate of the second drive transistor MN2 and the negative output terminal P− at the predetermined voltage.

When the voltage difference between the gate of the second drive transistor MN2 and the negative output terminal P− is less than the predetermined voltage, the clamp circuit (CLAMP CIRCUIT) returns to its initial state. When the clamp circuit is in the initial state, a path from the gate of the second drive transistor MN2 to the negative output terminal P− is in a bidirectional cutoff state.

In this embodiment, with the above arrangement, when the voltage difference between the gate of the second drive transistor MN2 and the negative output terminal P− is greater than or equal to the predetermined voltage, the clamp circuit (CLAMP CIRCUIT) is reversibly broken down to clamp the voltage difference between the gate of the second drive transistor MN2 and the negative output terminal P-at the predetermined voltage. Meanwhile, since the breakdown of the clamp circuit (CLAMP CIRCUIT) is reversible, the clamp circuit can return to its initial state when the voltage difference between the gate of the second drive transistor MN2 and the negative output terminal P− is less than the predetermined voltage.

Herein, reversible breakdown of the clamp circuit (CLAMP CIRCUIT)“ can be understood as the breakdown of a PN junction at the source and/or drain of the clamp circuit (CLAMP CIRCUIT), irreversible breakdown of the clamp circuit (CLAMP CIRCUIT) can be understood as damage to a gate oxide layer at the gate of the clamp circuit (CLAMP CIRCUIT).

The bidirectional cutoff state of the path from the gate of the second drive transistor MN2 to the negative output terminal P− can be understood as follows: current can neither flow from the gate of the second drive transistor MN2 to the negative output terminal P−, nor from the negative output terminal P−0 to the gate of the second drive transistor MN2.

When the clamp circuit (CLAMP CIRCUIT) is in the initial state, maintaining the path from the gate of the second drive transistor MN2 to the negative output terminal P− in the bidirectional cutoff state can avoid additional leakage consumption caused by a reverse current flowing from the negative output terminal P− to the gate of the second drive transistor MN2 (the reverse current is generated when the potential of the negative output terminal P− is higher than that of the negative electrode B− of the battery), thereby ensuring low-power requirement of the battery protection chip under extreme operating conditions.

In one embodiment, the clamp circuit (CLAMP CIRCUIT) comprises: a first unidirectional conductive device coupled between a first external connection terminal A and an intermediate node C, and configured to conduct unidirectionally from the first external connection terminal to the intermediate node C; and a second unidirectional conductive device coupled between a second external connection terminal B and the intermediate node C, and configured to conduct unidirectionally from the second external connection terminal to the intermediate node C.

The first external connection terminal A is coupled to the gate of the second drive transistor MN2, and the second external connection terminal B is coupled to the negative output terminal P−.

In this embodiment, through cooperation of the first unidirectional conductive device and the second unidirectional conductive device, the voltage difference between the gate of the second drive transistor MN2 and the negative output terminal P− is clamped within the predetermined voltage. Meanwhile, when the voltage difference between the gate of the second drive transistor MN2 and the negative output terminal P− is less than the predetermined voltage, the path from the gate of the second drive transistor MN2 to the negative output terminal P− is maintained in the bidirectional cutoff state.

In one embodiment, the first unidirectional conductive device is a diode, a PMOS transistor, or a bipolar transistor.

When the first unidirectional conductive device is a diode, an anode of the first unidirectional conductive device is coupled to the first external connection terminal, and a cathode of the first unidirectional conductive device is coupled to the intermediate node C.

When the first unidirectional conductive device is a PMOS transistor, a source, a gate, and a substrate of the first unidirectional conductive device are coupled to the first external connection terminal, and a drain of the first unidirectional conductive device is coupled to the intermediate node C.

When the first unidirectional conductive device is a bipolar transistor, an emitter of the first unidirectional conductive device is coupled to the first external connection terminal, and a base and a collector of the first unidirectional conductive device are coupled to the intermediate node C.

The second unidirectional conductive device is a diode, an NMOS transistor, or a bipolar transistor.

When the second unidirectional conductive device is a diode, an anode of the second unidirectional conductive device is coupled to the second external connection terminal, and a cathode of the second unidirectional conductive device is coupled to the intermediate node C.

When the second unidirectional conductive device is an NMOS transistor, a source, a gate, and a substrate of the second unidirectional conductive device are coupled to the second external connection terminal, and a drain of the second unidirectional conductive device is coupled to the intermediate node C.

When the second unidirectional conductive device is a bipolar transistor, an emitter of the second unidirectional conductive device is coupled to the second external connection terminal, and a base and a collector of the second unidirectional conductive device are coupled to the intermediate node C.

The bipolar transistor is an NPN transistor.

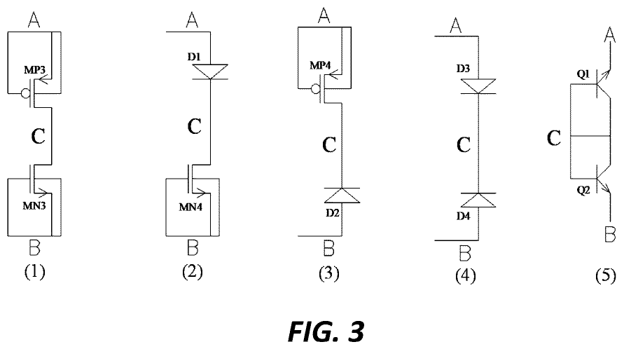

Exemplarily, a specific structure of the clamp circuit (CLAMP CIRCUIT) may be as shown in FIG. 3.

FIG. 3 (1) shows a structure of the clamp circuit (CLAMP CIRCUIT) when the first unidirectional conductive device is a PMOS transistor MP3 and the second unidirectional conductive device is an NMOS transistor MN3.

FIG. 3 (2) shows a structure of the clamp circuit (CLAMP CIRCUIT) when the first unidirectional conductive device is a diode D1 and the second unidirectional conductive device is an NMOS transistor MN4.

FIG. 3 (3) shows a structure of the clamp circuit (CLAMP CIRCUIT) when the first unidirectional conductive device is a PMOS transistor MP4 and the second unidirectional conductive device is a diode D2.

FIG. 3 (4) shows a structure of the clamp circuit (CLAMP CIRCUIT) when the first unidirectional conductive device is a diode D3 and the second unidirectional conductive device is a diode D4.

FIG. 3 (5) shows a structure of the clamp circuit (CLAMP CIRCUIT) when the first unidirectional conductive device is a bipolar transistor Q1 and the second unidirectional conductive device is a bipolar transistor Q2.

In one embodiment, when the voltage difference between a source and a drain of the first drive transistor MP2 exceeds a second predetermined voltage, the source and the drain of the first drive transistor MP2 are reversibly broken down, and the second resistor R2 is used for current limiting at this time.

A gate oxide breakdown voltage of the first drive transistor MP2 is higher than a source-to-drain breakdown voltage of the first drive transistor MP2, and the second predetermined voltage is between the gate oxide breakdown voltage of the first drive transistor MP2 and the source-to-drain breakdown voltage of the first drive transistor MP2. Therefore, when the voltage difference between the source and the drain of the first drive transistor MP2 is too high, the high voltage will preferentially break down the PN junction between the source and the drain of the first drive transistor MP2, and at this time, the source and the drain of the first drive transistor MP2 are turned on, which avoids the breakdown of the gate oxide layer of the first drive transistor MP2.

Specifically, when the PN junction between the source and the drain of the first drive transistor MP2 is broken down, the second resistor R2 is used for current limiting, which can prevent generation of strong current when the source and the drain of the first drive transistor MP2 are turned on, thereby avoiding a situation where the strong current burns the PN junction between the source and the drain of the first drive transistor MP2. Therefore, the reversible breakdown will not cause damage to the first drive transistor MP2. When the voltage difference between the source and the drain of the first drive transistor MP2 drops below the second predetermined voltage, the PN junction between the source and the drain of the first drive transistor MP2 can recover from the breakdown state to a normal working state.

In one embodiment, the source of the PMOS transistor MP2 is coupled to the positive electrode B+of the battery, and the drain of the PMOS transistor MP2 is coupled to the drive output terminal CO.

A source of the NMOS transistor MN2 is coupled to the negative output terminal P-, and a drain of the NMOS transistor MN2 is coupled to the drive output terminal CO.

The first drive transistor MP2 and the second drive transistor MN2 are manufactured using the same gate process as other MOS transistors in the protection drive circuit, so that the gate oxide breakdown voltage of the first drive transistor MP2 and the second drive transistor MN2 is equal to that of the other MOS transistors.

It can be understood that the “gate oxide breakdown voltage of the first drive transistor MP2 and the second drive transistor MN2 being equal to that of the other MOS transistors” can be interpreted as follows: the difference between the actual gate oxide breakdown voltage of the first drive transistor MP2 and the second drive transistor MN2 and the actual gate oxide breakdown voltage from the gate to the source of the other MOS transistors is less than or equal to a set error threshold.

In this embodiment, the above arrangement is used to unify the gate process requirements of all MOS transistors in the protection drive circuit, so that the gate oxide breakdown voltages of all MOS transistors in the protection drive circuit tend to be consistent. This further ensures that the process design of avoiding irreversible breakdown through reversible breakdown can be realized for all MOS transistors in the protection drive circuit, thereby reducing probability of irreversible breakdown of the MOS transistors in the protection drive circuit and extending a service life of the protection drive circuit.

At this time, when the clamp circuit (CLAMP CIRCUIT) comprises MOS transistors, the “other MOS transistors” may be understood as the MOS transistors included in the clamp circuit (CLAMP CIRCUIT).

In one embodiment, the protection drive circuit further comprises: a PMOS transistor MP1 and an NMOS transistor MN1.

A gate of the PMOS transistor MP1 is coupled to a digital input terminal C_CTRL, a source of the PMOS transistor MP1 is coupled to the positive electrode B+of the battery, a drain of the PMOS transistor MP1 is coupled to the control input terminal, the digital input terminal configured to receive a digital signal and the aforementioned control signal is formed based on the digital signal.

A gate of the NMOS transistor MN1 is coupled to the digital input terminal C_CTRL, a source of the PMOS transistor MP1 is coupled to the negative electrode B-of the battery, and a drain of the PMOS transistor MP1 is coupled to the control input terminal C_PRE.

The first drive transistor MP2 and the second drive transistor MN2 are manufactured using the same gate process as the MOS transistors MN1 and MP1, so that the gate oxide breakdown voltage of the first drive transistor MP2 and the second drive transistor MN2 is equal to the gate oxide breakdown voltage from the gate to the source of the MOS transistors MN1 and MP1.

The aforementioned other MOS transistors comprise the PMOS transistor MP1 and the NMOS transistor MN1.

In one embodiment, the predetermined voltage is greater than or equal to 6V and less than or equal to 10V.

The battery may be understood as a low-voltage battery with an output voltage of less than or equal to 5V.

The embodiments of the present invention are described above in conjunction with the accompanying drawings, but the present invention is not limited to the specific embodiments described above, the specific embodiments described above are merely illustrative and not limiting, and the person of ordinary skill in the field of the present invention, without departing from the purpose of the application and the scope of protection of the claims, may also make many forms, all of which are under the protection of the present invention.

Although preferred embodiments of the present invention have been described, additional changes and modifications to these embodiments may be made once the basic creative concepts are known to those skilled in the art. The appended claims are therefore intended to be interpreted to comprise preferred embodiments and all changes and modifications falling within the scope of the present invention.

Obviously, a person skilled in the art may make various changes and variations to the application without departing from the spirit and scope of the application. Thus, if these modifications and variations of the present invention fall within the scope of the claims and their equivalent technologies, the application is also intended to comprise these changes and variations.

1. A protection drive circuit for a battery system, comprising:
a first drive transistor and a second resistor coupled in series between a positive electrode of a battery and a drive output terminal, wherein a gate of the first drive transistor is coupled to a control input terminal configured to receive a control signal;
a second drive transistor coupled in series between the drive output terminal and a negative output terminal;
a first resistor coupled in series between a gate of the second drive transistor and the control input terminal; and
a clamp circuit coupled between the gate of the second drive transistor and the negative output terminal, wherein the clamp circuit is configured to clamp a voltage difference between the gate of the second drive transistor and the negative output terminal within a predetermined voltage.

2. The protection drive circuit according to claim 1, wherein a high level of the control signal is a voltage of the positive electrode of the battery, and a low level of the control signal is a voltage of a negative electrode of the battery;
when the control signal is at the low level, the first drive transistor is turned on, the second drive transistor is turned off, a drive signal output from the drive output terminal is at a high level, and the high level of the drive signal is the voltage of the positive electrode of the battery;
when the control signal is at the high level, the first drive transistor is turned off, the second drive transistor is turned on, the drive signal output from the drive output terminal is at a low level, and the low level of the drive signal is a voltage of the negative output terminal.

3. The protection drive circuit according to claim 1, wherein when the voltage difference between the gate of the second drive transistor and the negative output terminal is greater than or equal to the predetermined voltage, the clamp circuit is reversibly broken down to clamp the voltage difference between the gate of the second drive transistor and the negative output terminal at the predetermined voltage;
when the voltage difference between the gate of the second drive transistor and the negative output terminal is less than the predetermined voltage, the clamp circuit recovers to an initial state, and when the clamp circuit is in the initial state, a path from the gate of the second drive transistor to the negative output terminal is in a bidirectional cutoff state.

4. The protection drive circuit according to claim 3, wherein the clamp circuit comprises:
a first unidirectional conductive device coupled between a first external connection terminal and an intermediate node C and configured for unidirectional conduction from the first external connection terminal to the intermediate node C; and
a second unidirectional conductive device coupled between a second external connection terminal and the intermediate node C and configured for unidirectional conduction from the second external connection terminal to the intermediate node C;
wherein the first external connection terminal is coupled to the gate of the second drive transistor, and the second external connection terminal is coupled to the negative output terminal.

5. The protection drive circuit according to claim 4, wherein: the first unidirectional conductive device is a diode, a PMOS transistor, or a bipolar transistor.

6. The protection drive circuit according to claim 5, wherein:
when the first unidirectional conductive device is a diode, an anode of the first unidirectional conductive device is coupled to the first external connection terminal, and a cathode of the first unidirectional conductive device is coupled to the intermediate node C;
when the first unidirectional conductive device is a PMOS transistor, a source, a gate, and a substrate of the first unidirectional conductive device are coupled to the first external connection terminal, and a drain of the first unidirectional conductive device is coupled to the intermediate node C;
when the first unidirectional conductive device is a bipolar transistor, an emitter of the first unidirectional conductive device is coupled to the first external connection terminal, and a base and a collector of the first unidirectional conductive device are coupled to the intermediate node C,
wherein the bipolar transistor is an NPN bipolar transistor.

7. The protection drive circuit according to claim 4, wherein the second unidirectional conductive device is a diode, an NMOS transistor, or a bipolar transistor.

8. The protection drive circuit according to claim 7, wherein when the second unidirectional conductive device is a diode, an anode of the second unidirectional conductive device is coupled to the second external connection terminal, and a cathode of the second unidirectional conductive device is coupled to the intermediate node C;
when the second unidirectional conductive device is an NMOS transistor, a source, a gate, and a substrate of the second unidirectional conductive device are coupled to the second external connection terminal, and a drain of the second unidirectional conductive device is coupled to the intermediate node C;
when the second unidirectional conductive device is a bipolar transistor, an emitter of the second unidirectional conductive device is coupled to the second external connection terminal, and a base and a collector of the second unidirectional conductive device are coupled to the intermediate node C;
wherein the bipolar transistor is an NPN bipolar transistor.

9. The protection drive circuit according to claim 1, wherein when a voltage difference between a source and a drain of the first drive transistor exceeds a second predetermined voltage, a path between the source and the drain of the first drive transistor is reversibly broken down.

10. The protection drive circuit according to claim 2, wherein the drive signal is a charging drive signal, and the drive output terminal is coupled to a control terminal of a charging power switch;
a source and a substrate of the charging power switch are coupled to the negative output terminal;
when the charging drive signal is at the high level, the charging power switch is turned on, and when the charging drive signal is at the low level, the charging power switch is turned off.

11. The protection drive circuit according to claim 1, wherein the first drive transistor is a PMOS transistor MP2, a source of the PMOS transistor MP2 is coupled to the positive electrode of the battery, and a drain of the PMOS transistor MP2 is coupled to the drive output terminal;
the second drive transistor is an NMOS transistor MN2, a source of the NMOS transistor MN2 is coupled to the negative output terminal, and a drain of the NMOS transistor MN2 is coupled to the drive output terminal;
wherein the first drive transistor and the second drive transistor are manufactured using the same gate oxide process as other MOS transistors in the protection drive circuit, such that a gate oxide breakdown voltage of the first drive transistor and the second drive transistor is equal to a gate oxide breakdown voltage of the other MOS transistors.

12. The protection drive circuit according to claim 11, wherein the protection drive circuit further comprises:
a PMOS transistor MP1, wherein a gate of the PMOS transistor MP1 is coupled to a digital input terminal, a source of the PMOS transistor MP1 is coupled to the positive electrode of the battery, a drain of the PMOS transistor MP1 is coupled to the control input terminal, the digital input terminal configured to receive a digital signal;
an NMOS transistor MN1, wherein a gate of the NMOS transistor MN1 is coupled to the digital input terminal, a source of the NMOS transistor MN1 is coupled to the negative electrode of the battery, a drain of the NMOS transistor MN1 is coupled to the control input terminal;
wherein the first drive transistor and the second drive transistor are manufactured using the same gate oxide process as the transistors MN1 and MP1, such that the gate oxide breakdown voltage of the first drive transistor and the second drive transistor is equal to a gate oxide breakdown voltage of the transistors MN1 and MP1.

13. The protection drive circuit according to claim 1, wherein the predetermined voltage is greater than or equal to 6V and less than or equal to 10V.
